(19) United States
(12) Patent Application Publication
(10) Pub. No.: US 2026/0068267 A1
(43) Pub. Date: Mar. 5, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Yasuhiro SHIMIZU, Ibo Hyogo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/013,151

(22) Filed: Jan. 8, 2025

(30) Foreign Application Priority Data
Sep. 2, 2024 (JP) 2024-150893

(51) Int. Cl. H10D 64/23; H10D 30/66; H10D 62/832; H10D 64/62

(52) U.S. Cl. CPC H10D 64/252; H10D 30/66; H10D 62/8325; H10D 64/62

(57) ABSTRACT

A semiconductor device according to an embodiment includes a silicon carbide layer, a first electrode, a plurality of second electrodes, a third electrode, a conductive layer, a first conductive member, a second conductive member, and a recess. The first and second electrode are disposed on a first and second main surface of the silicon carbide layer, respectively. The third electrode faces a second silicon carbide region of the silicon carbide layer via a first insulating region. The conductive layer is electrically connected to the plurality of second electrodes, and has a first and second connection position to which the first and second conductive member is connected, respectively. The second conductive member is electrically connected to the third electrode. The recess is formed on an upper surface side of the conductive layer and is located on a side opposite to the first connection position with the second connection position interposed therebetween.

### CROSS-REFERENCE TO RELATED APPLICATIONS

This application is based upon and claims the benefit of priority from the prior Japanese Patent Application No.2024-150893, filed on Sep. 2, 2024; the entire contents of which are incorporated herein by reference.

### FIELD

Embodiments described herein relate generally to a semiconductor device.

### BACKGROUND

In a semiconductor device such as a metal oxide semiconductor field effect transistor (MOSFET) using silicon carbide, it is known that on-resistance increases by a decrease in gate-source voltage. In a semiconductor device, an increase in on-resistance is not preferable.

### BRIEF DESCRIPTION OF THE DRAWINGS

FIG. 1 is a plan view of a semiconductor device according to a first embodiment;

FIG. 2 is a cross-sectional view of the semiconductor device according to the first embodiment, taken along line A-A in FIG. 1;

FIG. 3 is a schematic plan view of the semiconductor device according to the first embodiment;

FIG. 4 is a plan view for explaining a flow of a current in the semiconductor device according to the first embodiment;

FIG. 5 is a cross-sectional view for explaining a flow of a current in the semiconductor device according to the first embodiment;

FIG. 6 is an equivalent circuit diagram of the semiconductor device according to the first embodiment;

FIG. 7A is a cross-sectional view for explaining an example of a process of manufacturing the semiconductor device according to the first embodiment;

FIG. 7B is a cross-sectional view for explaining the example of the process of manufacturing the semiconductor device according to the first embodiment, subsequent to FIG. 7A;

FIG. 7C is a cross-sectional view for explaining the example of the process of manufacturing the semiconductor device according to the first embodiment, subsequent to FIG. 7B;

FIG. 8 is a schematic plan view of a semiconductor device according to Modification 1 of the first embodiment;

FIG. 9 is a schematic plan view of a semiconductor device according to Modification 2 of the first embodiment;

FIG. 10 is a schematic plan view of a semiconductor device according to Modification 3 of the first embodiment;

FIG. 11 is a cross-sectional view of a semiconductor device according to a second embodiment, taken along line A-A in FIG. 1;

FIG. 12 is a cross-sectional view of a semiconductor device according to a third embodiment, taken along line A-A in FIG. 1;

FIG. 13 is a cross-sectional view of a semiconductor device according to Modification of the third embodiment, taken along line A-A in FIG. 1; and

FIG. 14 is a schematic plan view of a semiconductor device according to a fourth embodiment.

### DETAILED DESCRIPTION

A semiconductor device according to an embodiment includes a silicon carbide layer, a first electrode, a plurality of second electrodes, a third electrode, a conductive layer, a first conductive member, a second conductive member, and a recess. The silicon carbide layer has a first main surface and a second main surface. The silicon carbide layer includes a first-conductivity-type first silicon carbide region, a second-conductivity-type second silicon carbide region disposed between the second main surface and the first silicon carbide region, and a first-conductivity-type third silicon carbide region disposed between the second main surface and the second silicon carbide region. The first electrode is disposed on the first main surface. The plurality of second electrodes are disposed on the second main surface. The third electrode faces the second silicon carbide region via a first insulating region. The conductive layer is electrically connected to the plurality of second electrodes, and has a first connection position and a second connection position on an upper surface thereof. The first conductive member is connected to the first connection position and is electrically connected to the conductive layer. The second conductive member is connected to the second connection position and is electrically connected to the third electrode and the conductive layer. The recess is formed on an upper surface side of the conductive layer and is located on a side opposite to the first connection position with the second connection position interposed therebetween.

Hereinafter, embodiments according to the present invention will be described with reference to the drawings. The embodiments do not limit the present invention. The drawings are schematic or conceptual, and a ratio between portions and the like are not necessarily the same as actual ones. In the specification and the drawings, elements similar to those described above regarding the previously described drawings are denoted by the same reference numerals, and detailed description thereof is appropriately omitted.

For convenience of description, a source electrode side is also referred to as “upper”, and a drain electrode side is also referred to as “lower”. Note that this expression is for convenience and independent of the direction of gravity.

In the following description, notations of n⁺, n, n⁻, p⁺, p, and p⁻ may be used to represent a relative level of an impurity concentration in each conductivity type. That is, n⁺ indicates that an n-type impurity concentration is relatively higher than n, and n⁻ indicates that the n-type impurity concentration is relatively lower than n. In addition, p⁺ indicates that a p-type impurity concentration is relatively higher than p, and p⁻ indicates that the p-type impurity concentration is relatively lower than p. When both a p-type impurity and an n-type impurity are contained in each region, each of these notations represents a relative level of a net impurity concentration after these impurities are compensated for each other. The n-type, n⁺-type, and n⁻-type are examples of the first conductivity type in the claims. The p-type, p⁺-type, and p⁻-type are examples of the second conductivity type in the claims. Note that, in the following description, the n-type and the p-type may be inverted. That is, the first conductivity type may be p-type.

An impurity concentration of a semiconductor region can be measured by, for example, secondary ion mass spectrometry (SIMS). A relative level of the impurity concentration can also be determined from a level of a carrier concentration obtained by, for example, scanning capacitance microscopy (SCM).

In addition, the planar shape, depth, and the like of the recess can be measured by, for example, analyzing a surface and a cross section of a semiconductor device with an optical microscope, a transmission electron microscope (TEM), an energy dispersive X-ray spectroscopy (EDX), or a scanning electron microscope (SEM).

Note that, for example, terms such as “equal” and “same”, dimensions, values of physical characteristics, and the like, which specify shapes, geometric conditions, physical characteristics, and degrees thereof, used in the present specification, are interpreted including a range in which similar functions can be expected, without being bound by strict meanings.

### First Embodiment

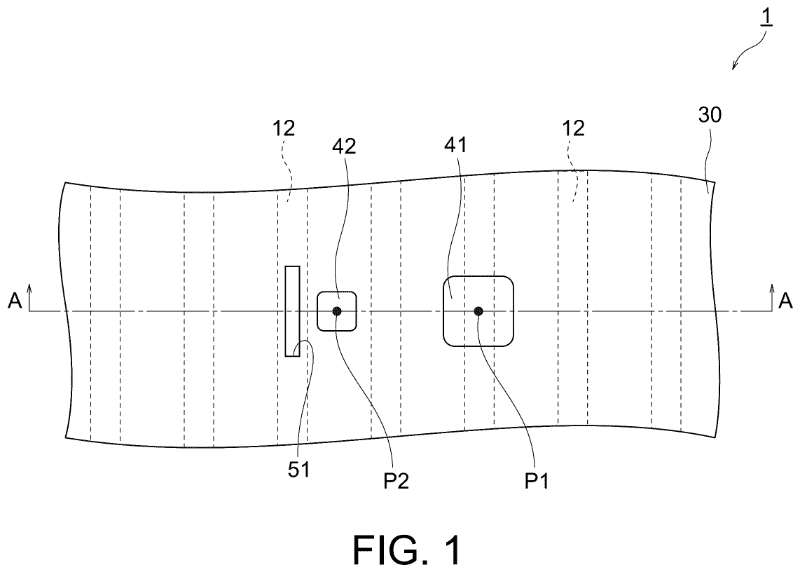

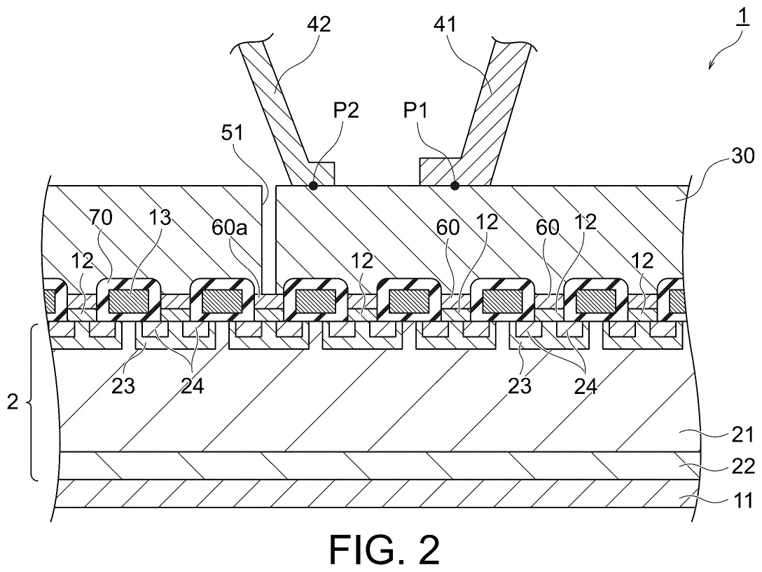

A semiconductor device 1 according to a first embodiment will be described with reference to FIGS. 1 and 2. FIG. 1 is a plan view of the semiconductor device 1 according to the first embodiment. FIG. 2 is a cross-sectional view of the semiconductor device 1 according to the first embodiment, taken along line A-A in FIG. 1. Note that, in FIG. 1, as a conductive member 41 and a conductive member 42, portions in contact with an upper surface of a conductive layer 30 are illustrated.

The semiconductor device 1 is, for example, a MOSFET. In the present embodiment, a case where the semiconductor device 1 is a vertical MOSFET having a planar gate structure will be described as an example. Note that the semiconductor device 1 may be a vertical MOSFET having a trench gate structure or the like.

As illustrated in FIG. 2, the semiconductor device 1 according to the present embodiment includes a silicon carbide layer 2, a drain electrode 11, a plurality of source electrodes 12, a gate electrode 13, a conductive layer 30, a conductive member 41, a conductive member 42, a recess 51, a plurality of barrier metals 60, and an insulating region (first insulating region) 70.

The silicon carbide layer 2 includes a lower surface (first main surface) and an upper surface (second main surface). The silicon carbide layer 2 includes a drift region (first silicon carbide region) 21, a drain region (first silicon carbide region) 22, a base region (second silicon carbide region) 23, and a source region (third silicon carbide region) 24 therein. Details of each of the regions will be described later.

The silicon carbide layer 2 may be an epitaxial layer, a semiconductor substrate, or a semiconductor substrate and an epitaxial layer disposed on the semiconductor substrate. The silicon carbide layer 2 is made of single crystal silicon carbide (SiC). In this case, for example, nitrogen (N), phosphorus (P), arsenic (As), or antimony (Sb) is used as an n-type impurity, and for example, aluminum (Al) or boron (B) is used as a p-type impurity.

The drain electrode 11 functions as a drain electrode of the MOSFET. The drain electrode 11 is disposed on a lower surface of the silicon carbide layer 2, is in contact with the drain region 22, and is electrically connected to the drain region 22. The drain electrode 11 is an example of the first electrode in the claims. The drain electrode 11 is made of a material containing at least one of, for example, nickel (Ni), titanium (Ti), and aluminum (Al).

The source electrode 12 functions as a source electrode of the MOSFET. The source electrode 12 is disposed on an upper surface of the silicon carbide layer 2, is in contact with the base region 23 and the source region 24, and is electrically connected to the base region 23 and the source region 24. The source electrode 12 is an example of the second electrode in the claims. In the present embodiment, the plurality of source electrodes 12 are disposed on the upper surface of the silicon carbide layer 2. The source electrode 12 is made of a material containing at least one of, for example, nickel (Ni), titanium (Ti), and aluminum (Al).

The barrier metal 60 is disposed on the source electrode 12. In the present embodiment, the plurality of barrier metals 60 are disposed on the plurality of source electrodes 12, respectively. The barrier metal 60 is made of a material containing at least one of, for example, titanium (Ti), tungsten (W), tantalum (Ta), titanium nitride, tungsten nitride, and tantalum nitride. Note that, one barrier metal 60 disposed on one of the plurality of source electrodes 12 may be formed instead of the plurality of barrier metals 60.

In the present embodiment, as illustrated in FIG. 1, each of the plurality of source electrodes 12 extends in one direction (vertical direction in FIG. 1) orthogonal to a thickness direction of the silicon carbide layer 2. That is, the plurality of source electrodes 12 have a stripe planar shape. Note that the planar shape of the plurality of source electrodes 12 is not limited to that illustrated in FIG. 1. For example, at least one of the plurality of source electrodes 12 may have a dot-shaped planar shape.

As illustrated in FIG. 2, the insulating region 70 is disposed on an upper surface of the silicon carbide layer 2. The insulating region 70 is disposed so as to be sandwiched between the source electrodes 12. In the present embodiment, the insulating region 70 is disposed so as to be sandwiched between two-layer structures each including the source electrode 12 and the barrier metal 60 thereon. The insulating region 70 is embedded in the conductive layer 30. The insulating region 70 is an insulating film containing, for example, a silicon oxide or a silicon nitride.

The gate electrode 13 functions as a gate electrode of the MOSFET. The gate electrode 13 is disposed in the insulating region 70, and is electrically insulated from the silicon carbide layer 2 by the insulating region 70. The gate electrode 13 controls a current I_{DS} (drain-source current) flowing between the drain electrode 11 and the source electrode 12. The gate electrode 13 is an example of the third electrode in the claims. The gate electrode 13 is made of, for example, polysilicon containing a p-type or n-type impurity. When a voltage is applied to the gate electrode 13, a channel is formed in the base region 23, and a carrier flows between the drift region 21 and the source region 24. As a result, the MOSFET is turned on.

The conductive layer 30 is disposed so as to embed the plurality of source electrodes 12, and is electrically connected to the plurality of source electrodes 12. In the present embodiment, the conductive layer 30 embeds the plurality of source electrodes 12 via the plurality of barrier metals 60, respectively. In other words, the plurality of barrier metals 60 are disposed between the plurality of source electrodes 12 and the conductive layer 30, respectively. The conductive layer 30 is made of a material containing at least one of, for example, aluminum (Al), copper (Cu), titanium (Ti), and tungsten (W). The conductive layer 30 is also referred to as a source metal. Note that the conductive layer 30 may be made of the same material as the barrier metal 60 or may be made of a different material from the barrier metal 60.

As illustrated in FIGS. 1 and 2, the conductive layer 30 has a connection position P1 to which the conductive member 41 is connected and a connection position P2 to which the conductive member 42 is connected on an upper surface thereof. That is, the conductive member 41 and the conductive member 42 are connected to the same conductive layer 30. The connection position P1 is an example of the first connection position in the claims. The connection position P2 is an example of the second connection position in the claims. Note that the connection position P1 is a center of a portion with which the conductive member 41 is in contact on the upper surface of the conductive layer 30 (hereinafter, also referred to as a “contact portion of the conductive member 41”), for example, a geometric center of gravity of the portion. The connection position P2 is a center of a portion with which the conductive member 42 is in contact on the upper surface of the conductive layer 30 (hereinafter, also referred to as a “contact portion of the conductive member 42”), for example, a geometric center of gravity of the portion. Note that the shapes of the contact portion of the conductive member 41 and the contact portion of the conductive member 42 are not limited to those illustrated in FIG. 1.

The conductive member 41 and the conductive member 42 are wires, metal pieces, or the like. In a case where each of the conductive member 41 and the conductive member 42 is a wire, a constituent material thereof is, for example, aluminum or an aluminum alloy. In a case where each of the conductive member 41 and the conductive member 42 is a metal piece, a constituent material thereof is, for example, copper or a copper alloy. Note that at least one of the conductive member 41 and the conductive member 42 may be a bundle of a plurality of wires.

The conductive member 41 is electrically connected to the conductive layer 30. The current I_{DS} flowing between the drain electrode 11 and the source electrode 12 flows through the conductive member 41. For example, a current that has flowed from the drain electrode 11 to the source electrode 12 passes through the conductive layer 30 and then flows into the conductive member 41. On the contrary, a current that has flowed from the conductive member 41 to the conductive layer 30 flows from the source electrode 12 to the drain electrode 11. The conductive member 41 is an example of the first conductive member in the claims. The conductive member 41 is also referred to as a source wire or a source force wire.

The conductive member 42 is electrically connected to the gate electrode 13 and the conductive layer 30. A drive voltage V_{DRV} for controlling the current I_{DS} is applied between the conductive member 42 and the gate electrode 13. By connecting such a conductive member 42, as compared with a case where the conductive member 42 is not connected and the drive voltage V_{DRV} is applied to the conductive member 41, it is possible to suppress a voltage actually applied between the source electrode 12 and the gate electrode 13, that is, the gate-source voltage V_{GS} from being lower than the drive voltage V_{DRV} due to resistance of the conductive member 41 and the current I_{DS} flowing through the conductive member 41. The conductive member 42 is an example of the second conductive member in the claims. The conductive member 42 is also referred to as a source sense wire. Note that, as illustrated in FIG. 2, the diameter of the conductive member 42 may be smaller than the diameter of the conductive member 41.

The recess 51 is formed on an upper surface side of the conductive layer 30, and is located on a side opposite to the connection position P1 with the connection position P2 interposed therebetween. The recess 51 is, for example, a portion from which a part of the conductive layer 30 is removed. As illustrated in FIG. 1, in the present embodiment, the planar shape of the recess 51 is a slit, that is, a linear shape. Note that the planar shape of the recess 51 is not limited to the linear shape, and may be any shape such as a dot shape, a wavy shape, or a zigzag shape.

As illustrated in FIG. 2, in the present embodiment, upper surface of barrier metals 60a, which are some of the plurality of barrier metals 60, are exposed on a bottom surface of the recess 51. Note that the bottom surface of the recess 51 does not have to reach the barrier metal 60.

Note that, although not illustrated, a part of a sealing material of the semiconductor device 1 may flow into the recess 51. That is, at least a part of the recess 51 may be filled with a sealing material that seals the conductive layer 30, the conductive member 41, and the conductive member 42.

In the example of FIG. 2, the recess 51 is located on the barrier metal 60. Without being limited thereto, the recess 51 may be located on the insulating region 70 or may be located over the barrier metal 60 and the insulating region 70. That is, a positional relationship between the recess 51, and the barrier metal 60 and the insulating region 70 is arbitrary. In the example of FIG. 1, a longitudinal direction of the recess 51 coincides with an extending direction of the source electrode 12. Without being limited thereto, the longitudinal direction of the recess 51 may be different from the extending direction of the source electrode 12.

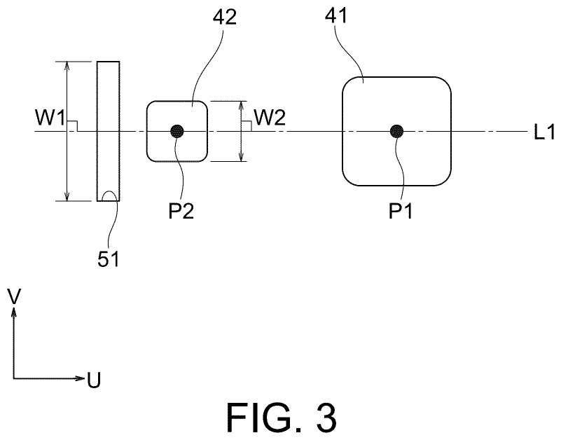

Here, the shape of the recess 51 will be described in more detail with reference to FIG. 3. FIG. 3 is a schematic plan view of the semiconductor device 1 according to the first embodiment. Note that, in FIG. 3, a direction directed from the connection position P2 toward the connection position P1 on the upper surface of the conductive layer 30 is defined as a U-axis direction, and a direction orthogonal to the U-axis direction on the upper surface of the conductive layer 30 is defined as a V-axis direction. The U-axis direction is an example of the first direction in the claims. The V-axis direction is an example of the second direction in the claims. Note that, in the example of FIGS. 1 and 3, the U-axis direction directed from the connection position P2 toward the connection position P1 is orthogonal to an extending direction of the source electrode 12. Without being limited thereto, the U-axis direction may be different from the extending direction of the source electrode 12. For example, the U-axis direction may be parallel to or oblique to the extending direction of the source electrode 12.

As illustrated in FIG. 3, the recess 51 of the present embodiment is symmetrical with respect to a straight line L1 passing through the connection position P1 and the connection position P2. The straight line L1 is an example of the first straight line in the claims. That is, in FIG. 3, a portion above the straight line L1 and a portion below the straight line L1 in the recess 51 have symmetrical shapes. Note that the recess 51 does not have to be symmetrical with respect to the straight line L1 passing through the connection position P1 and the connection position P2.

The length of the recess 51 in a longitudinal direction is equal to or longer than the width of the conductive member 42 connected to the upper surface of the conductive layer 30. More specifically, a length W1 of the recess 51 in the V-axis direction is equal to or longer than a length W2 of a portion in contact with the upper surface of the conductive layer 30 in the conductive member 42. In other words, the length of the recess 51 in the longitudinal direction is equal to or longer than the width of the contact portion of the conductive member 42.

Hereinafter, an example of an internal configuration of the silicon carbide layer 2 will be described with reference to FIG. 2. Note that the internal configuration of the silicon carbide layer 2 is not limited to that described below. In the subsequent drawings, the internal configuration of the silicon carbide layer 2 is appropriately omitted.

As illustrated in FIG. 2, the silicon carbide layer 2 includes, for example, the drift region 21, the drain region 22, the base region 23, and the source region 24 therein.

The drift region 21 functions as a drift region of the MOSFET. The drift region 21 is disposed on the drain region 22 (above the drain electrode 11). The drift region 21 is, for example, an n⁻-type semiconductor region. An n-type impurity concentration of the drift region 21 is, for example, 4×10¹⁴ cm⁻³ or more and 1×10¹⁷ cm⁻³ or less.

The drain region 22 functions as a drain region of the MOSFET. The drain region 22 is disposed between the drift region 21 and the drain electrode 11. The drain region 22 is in contact with the drain electrode 11 and is in ohmic contact with the drain electrode 11. The drain region 22 is, for example, an n⁺-type semiconductor region. An n-type impurity concentration of the drain region 22 is, for example, 1×10¹⁸ cm⁻³ or more and 1×10²¹ cm⁻³ or less.

The base region 23 functions as a base region of the MOSFET. The base region 23 is disposed on the drift region 21. The base region 23 is, for example, a p-type semiconductor region. A p-type impurity concentration of the base region 23 is, for example, 1×10¹⁶ cm⁻³ or more and 1×10²¹ cm⁻³ or less. In the example of FIG. 2, the base region 23 includes a first portion located below the source region 24, a second portion extending from the first portion toward an upper surface of the silicon carbide layer 2 and in contact with the source electrode 12, and a third portion extending from the first portion toward the upper surface of the silicon carbide layer 2 and in contact with the insulating region 70 below the gate electrode 13. Note that the second portion may be a p⁺-type semiconductor region. That is, a p-type impurity concentration of the second portion may be higher than a p-type impurity concentration of each of the first portion and the third portion.

The source region 24 functions as a source region of the MOSFET. The source region 24 is located between the base region 23 and the source electrode 12. The source region 24 is in contact with the source electrode 12 and is in ohmic contact with the source electrode 12. The source region 24 is, for example, an n⁺-type semiconductor region. An n-type impurity concentration of the source region 24 is, for example, 1×10¹⁸ cm⁻³ or more and 1×10²¹ cm⁻³ or less.

Note that the semiconductor device 1 may further include a field plate electrode (FP electrode) disposed in the silicon carbide layer 2 via an insulating region. The FP electrode is electrically insulated from the silicon carbide layer 2 by the insulating region, and is electrically connected to the source electrode 12. With such an FP electrode, when the MOSFET is in an off state, a depletion layer extends from the FP electrode to the drift region 21 around the FP electrode by a voltage applied between the drain electrode 11 and the source electrode 12. This depletion layer is connected to a depletion layer of an adjacent FP electrode, whereby a withstand voltage of the semiconductor device 1 can be improved.

As described above, the semiconductor device 1 according to the present embodiment includes the silicon carbide layer 2, the drain electrode 11, the plurality of source electrodes 12, the gate electrode 13, the conductive layer 30, and the recess 51. The silicon carbide layer 2 has a lower surface and an upper surface. The drain electrode 11 is disposed on the lower surface of the silicon carbide layer 2. The plurality of source electrodes 12 are disposed on the upper surface of the silicon carbide layer 2. The gate electrode 13 is electrically insulated from the silicon carbide layer 2 by the insulating region 70, and controls the current I_{DS} flowing between the drain electrode 11 and the plurality of source electrodes 12. The conductive layer 30 is disposed so as to embed the plurality of source electrodes 12, and is electrically connected to the plurality of source electrodes 12. The conductive layer 30 has the connection position P1 to which the conductive member 41 is connected and the connection position P2 to which the conductive member 42 is connected on an upper surface thereof. The current I_{DS} flows through the conductive member 41. The drive voltage V_{DRV} is applied between the conductive member 42 and the gate electrode 13. The recess 51 is formed on an upper surface side of the conductive layer 30, and is located on a side opposite to the connection position P1 with the connection position P2 interposed therebetween.

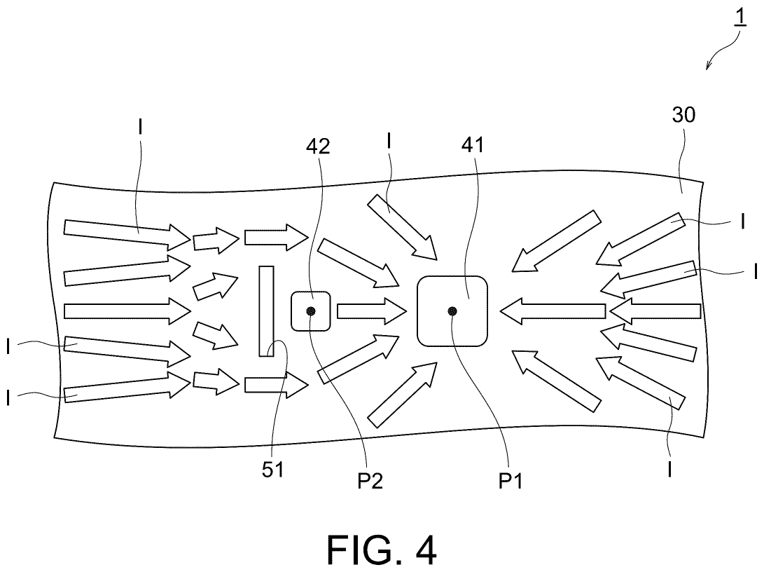

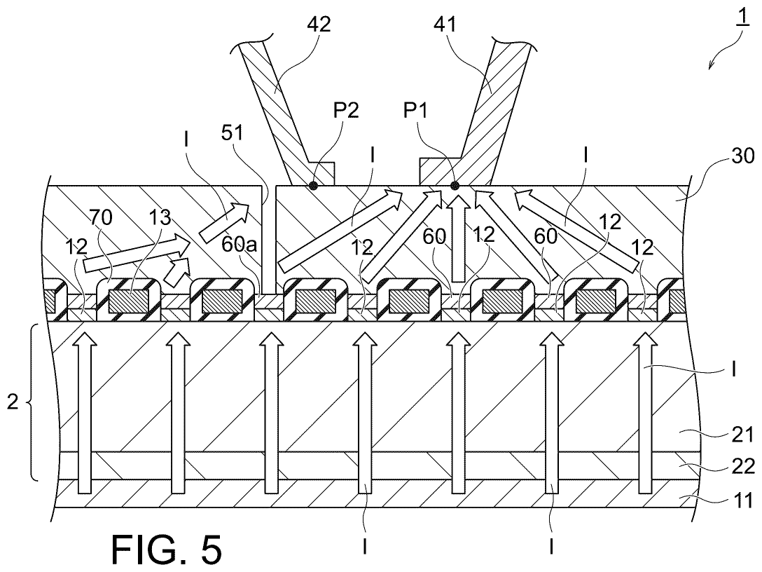

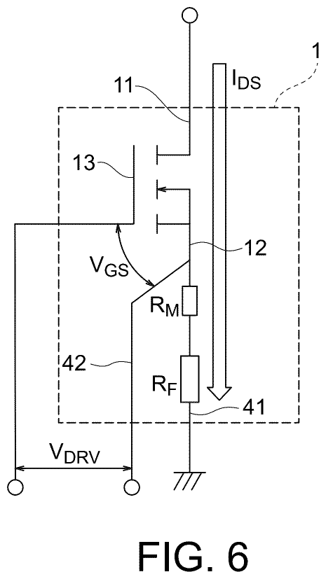

According to the present embodiment, on-resistance of the semiconductor device 1 can be reduced as compared with a case where there is no recess 51. Hereinafter, functions and effects of the present embodiment will be described in detail with reference to FIGS. 4 to 6. FIG. 4 is a plan view for explaining a flow of a current in the semiconductor device 1 according to the first embodiment. FIG. 5 is a cross-sectional view for explaining a flow of a current in the semiconductor device 1 according to the first embodiment, taken along line A-A in FIG. 1. FIG. 6 is an equivalent circuit diagram of the semiconductor device 1 according to the first embodiment. Note that, in FIGS. 4 and 5, symbol I schematically represents a path of a current flowing from the drain electrode 11 to the conductive member 41 via the source electrode 12, the barrier metal 60, and the conductive layer 30. In FIG. 6, R_{M} represents resistance caused by the conductive layer 30 between the source electrode 12 and the conductive member 41, and R_{F} represents resistance of the conductive member 41.

As illustrated in FIG. 5, when the semiconductor device 1 as a MOSFET is in an on state, the current I first flows in the silicon carbide layer 2 from the drain electrode 11 toward the source electrode 12. Thereafter, as illustrated in FIGS. 4 and 5, the current I that has passed through the source electrode 12 and the barrier metal 60 flows in the conductive layer 30 from the barrier metal 60 toward the connection position P1 of the conductive member 41.

Here, in the present embodiment, with the recess 51, as illustrated in FIG. 4, among the currents I flowing out from the source electrodes 12 and flowing in the conductive layer 30, a current flowing from a side opposite to the connection position P1 with the connection position P2 interposed therebetween to the connection position P1 flows to the connection position P1 so as to bypass the connection position P2 without passing through the connection position P2. That is, the contact portion of the conductive member 42 is separated from at least one of the plurality of currents I. As a result, a current passing through the contact portion of the conductive member 42 can be reduced as compared with a case where there is no recess 51. As a result, a voltage drop at the contact portion of the conductive member 42 can be suppressed. That is, as illustrated in FIG. 6, the conductive member 42 is substantially connected between the source electrode 12 and a resistance R_{M}. Therefore, according to the present embodiment, it is possible to suppress the gate-source voltage V_{GS} actually applied between the source electrode 12 and the gate electrode 13 from being lower than the drive voltage V_{DRV}.

In general, in a semiconductor device having a silicon carbide layer, it is known that on-resistance of the semiconductor device increases by a decrease in the gate-source voltage V_{GS}. Therefore, according to the present embodiment, a decrease in the gate-source voltage V_{GS} can be suppressed and the on-resistance of the semiconductor device 1 can be reduced as compared with a case where there is no recess 51.

In addition, the density of a current in the conductive layer 30 increases as it is closer to the conductive member 41. Therefore, when the conductive member 42 is close to the conductive member 41, a voltage drop at the contact portion of the conductive member 42 increases. According to the present embodiment, with the recess 51, the on-resistance of the semiconductor device 1 can be effectively reduced when the conductive member 42 is close to the conductive member 41.

In addition, according to the present embodiment, the recess 51 is symmetrical with respect to the straight line L1 passing through the connection position P1 and the connection position P2. As a result, for example, in FIG. 4, a vertical component of a current flowing toward the connection position P2 via an upper side of the recess 51 and a vertical component of a current flowing toward the connection position P2 via a lower side of the recess 51 cancel each other. Therefore, a current passing through the contact portion of the conductive member 42 can be further reduced.

In addition, in the present embodiment, the length of the recess 51 in the longitudinal direction is equal to or longer than the width of the conductive member 42 connected to the upper surface of the conductive layer 30. As a result, the current passing through the contact portion of the conductive member 42 can be further reduced.

In addition, in the present embodiment, the conductive member 41 and the conductive member 42 are connected to the same conductive layer 30. As a result, it is possible to suppress a decrease in the area of the conductive layer 30 that contributes to conduction of the current I, for example, as compared with a case where the conductive member 41 is connected to the first conductive layer and the conductive member 42 is connected to the second conductive layer physically separated from the first conductive layer. Therefore, the on-resistance of the semiconductor device 1 can be further reduced.

### Method For Manufacturing Semiconductor Device 1

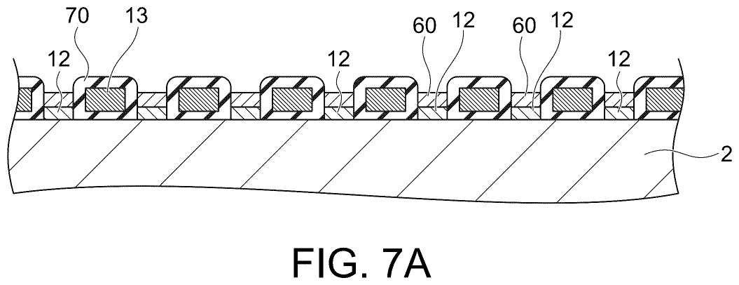

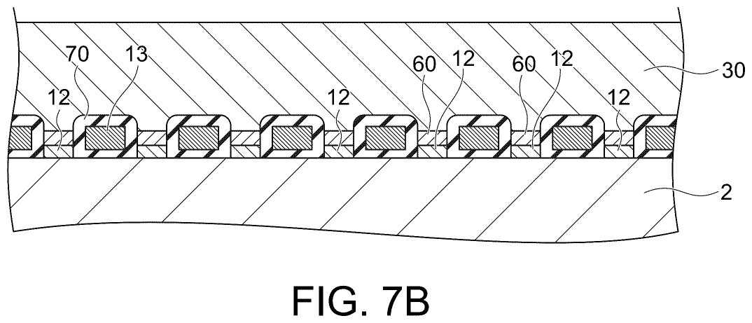

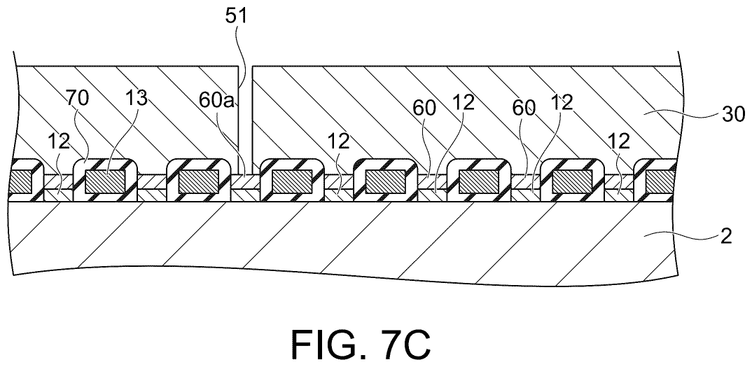

Next, an example of a method for manufacturing the semiconductor device 1 according to the present embodiment will be described with reference to FIGS. 7A to 7C. FIGS. 7A to 7C are cross-sectional views for explaining an example of a process of manufacturing the semiconductor device 1 according to the first embodiment, taken along line A-A in FIG. 1.

First, as illustrated in FIG. 7A, a semiconductor device member including the silicon carbide layer 2, the source electrode 12, the gate electrode 13, the barrier metal 60, and the insulating region 70 is prepared. Although not illustrated, a semiconductor region such as the drift region 21 is formed in the silicon carbide layer 2.

Next, as illustrated in FIG. 7B, the conductive layer 30 is formed on an upper surface of the silicon carbide layer 2 so as to embed the barrier metal 60 and the insulating region 70. Thereafter, although not illustrated, the drain electrode 11 is formed on a lower surface of the silicon carbide layer 2. Note that the drain electrode 11 may be formed before the conductive layer 30 is formed.

Next, as illustrated in FIG. 7C, a portion located on the barrier metal 60a in the conductive layer 30 is removed by reactive ion etching (RIE) or the like. As a result, the recess 51 is formed on an upper surface of the conductive layer 30. An upper surface of the barrier metal 60a is exposed on a bottom surface of the recess 51.

Thereafter, although not illustrated, first ends of the conductive member 41 and the conductive member 42 are connected to the upper surface of the conductive layer 30, and second ends of the conductive member 41 and the conductive member 42 are connected to an inner lead of a lead frame using a bonding material such as solder. Thereafter, the conductive layer 30, the conductive member 41, and the conductive member 42 are sealed with a sealing material.

Through the above steps, the semiconductor device 1 according to the present embodiment is manufactured.

Note that, in the method for manufacturing the semiconductor device 1 according to the present embodiment, the conductive layer 30 may be made of a material different from the barrier metal 60. This facilitates formation of the recess 51 in the step described with reference to FIG. 7C. Specifically, it is possible to suppress the barrier metal 60 from being removed in RIE for removing a part of the conductive layer 30.

Hereinafter, some Modifications of the first embodiment in which the planar shape of the recess 51 is changed will be described focusing on a difference from the first embodiment. Also in Modifications described below, as in the above first embodiment, on-resistance of a semiconductor device can be reduced as compared with a case where there is no recess.

### Modification 1 of First Embodiment

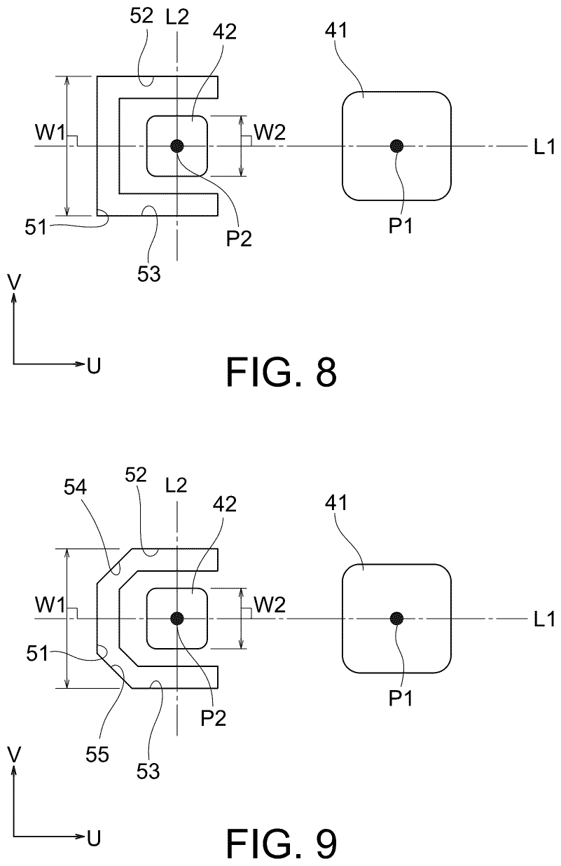

A semiconductor device according to Modification 1 of the first embodiment will be described with reference to FIG. 8. FIG. 8 is a schematic plan view of the semiconductor device according to Modification 1 of the first embodiment.

As illustrated in FIG. 8, the semiconductor device according to the present Modification has a U-shaped recess, that is, a rectangular recess from which one side is removed. More specifically, in the present Modification, the recess 51 has a first end (upper end in FIG. 8) and a second end (lower end in FIG. 8) on a side opposite to the first end. In addition, the semiconductor device according to the present Modification further has a recess 52 formed on an upper surface side of the conductive layer 30 and connected to the first end of the recess 51, and a recess 53 formed on the upper surface side of the conductive layer 30 and connected to the second end of the recess 51. The recess 52 is an example of the second recess in the claims. The recess 53 is an example of the third recess in the claims. Note that the recess 51 of the present Modification has the same shape as the recess 51 of the first embodiment described with reference to FIG. 3. In addition, the recess 52 and the recess 53 each have a linear shape whose longitudinal direction is orthogonal to a longitudinal direction (V-axis direction) of the recess 51.

The recess 53 sandwiches the connection position P2 together with the recess 52. That is, the recess 53 is located on a side opposite to the recess 52 with the connection position P2 interposed therebetween. As a result, a current passing through the contact portion of the conductive member 42 can be further reduced.

In addition, a length W1 of the recess formed by the recesses 51, 52, and 53 in the V-axis direction is longer than a length W2 of the conductive member 42 in the V-axis direction. As a result, a current passing through the contact portion of the conductive member 42 can be further reduced.

In addition, the recess formed by the recesses 51, 52, and 53 is symmetrical with respect to the straight line L1 passing through the connection position P1 and the connection position P2. As a result, a current passing through the contact portion of the conductive member 42 can be further reduced.

In addition, the recess 52 and the recess 53 extend toward the conductive member 41 over a straight line L2 perpendicular to the straight line L1 and passing through the connection position P2. As a result, a current passing through the contact portion of the conductive member 42 can be further reduced. The straight line L2 is an example of the second straight line in the claims.

Note that the conductive layer 30 may be disposed between the recess 51 and the recess 52 while the recess 51 and the recess 52 are not continuous. Similarly, the conductive layer 30 may be disposed between the recess 51 and the recess 53 while the recess 51 and the recess 53 are not continuous.

### Modification 2 of First Embodiment

A semiconductor device according to Modification 2 of the first embodiment will be described with reference to FIG. 9. FIG. 9 is a schematic plan view of the semiconductor device according to Modification 2 of the first embodiment.

As illustrated in FIG. 9, the semiconductor device according to the present Modification has a U-shaped recess. More specifically, in the present Modification, the recess 51 has a first end (upper end in FIG. 9) and the second end (lower end in FIG. 9) on a side opposite to the first end. In addition, the semiconductor device according to the present Modification further has a recess 52 formed on an upper surface side of the conductive layer 30 and connected to the first end of the recess 51, and a recess 53 formed on the upper surface side of the conductive layer 30 and connected to the second end of the recess 51. More specifically, the semiconductor device according to the present Modification further has a recess 52 connected to the first end of the recess 51 via a connection recess 54, and a recess 53 connected to the second end of the recess 51 via a connection recess 55. The connection recess 54 extends from the first end of the recess 51 toward the connection position P1 and connects the recess 51 and the recess 52. The connection recess 55 extends from the second end of the recess 51 toward the connection position P1 and connects the recess 51 and the recess 53. In addition, the recess 51 and the recess 52 are continuous via the connection recess 54, and the recess 51 and the recess 53 are continuous via the connection recess 55. The connection recess 54 is an example of the first connection recess in the claims. The connection recess 55 is an example of the second connection recess in the claims. Note that the recess 51 of the present Modification has a linear shape similar to that of the recess 51 of the first embodiment described with reference to FIG. 3. Note that the length of the recess 51 of the present Modification in a longitudinal direction is shorter than the length W1 of the recess 51 of the first embodiment in the longitudinal direction. In addition, the recess 52 and the recess 53 each have a linear shape whose longitudinal direction is orthogonal to a longitudinal direction (V-axis direction) of the recess 51.

In addition, in the example of FIG. 9, the connection recess 54 and the connection recess 55 each have a linear shape. In addition, longitudinal directions of the connection recess 54 and the connection recess 55 are each inclined at about 45° with respect to the longitudinal direction (V-axis direction) of the recess 51. Without being limited thereto, the connection recess 54 may have a curved shape such as an arc that smoothly connects the recess 51 and the recess 52. Similarly, the connection recess 55 may have a curved shape that smoothly connects the recess 51 and the recess 53.

In addition, the recess formed by the recesses 51, 52, and 53 and the connection recesses 54 and 55 is symmetrical with respect to the straight line L1 passing through the connection position P1 and the connection position P2. As a result, a current passing through the contact portion of the conductive member 42 can be further reduced.

### Modification 3 of First Embodiment

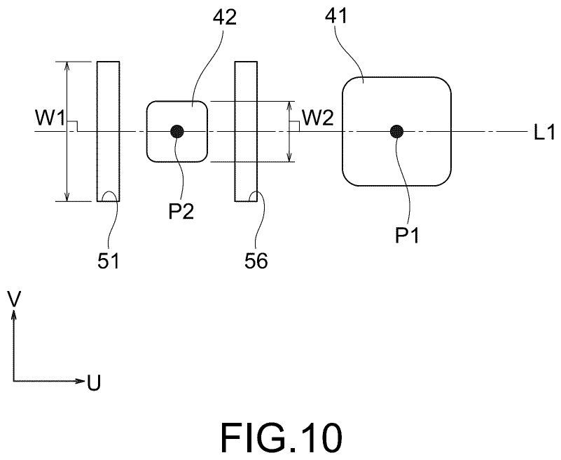

A semiconductor device according to Modification 3 of the first embodiment will be described with reference to FIG. 10. FIG. 10 is a schematic plan view of the semiconductor device according to Modification 3 of the first embodiment.

As illustrated in FIG. 10, the semiconductor device according to the present Modification has a II-shaped recess. More specifically, the semiconductor device according to the present Modification further has a recess 56 in addition to the recess 51.

The recess 56 is formed in the conductive layer 30, and is located on a side opposite to the recess 51 with the connection position P2 interposed therebetween, that is, on the connection position P1 side. Note that the recess 56 is located between the connection position P2 and the connection position P1. The recess 56 is an example of the fourth recess in the claims. In the example of FIG. 10, the recess 56 is parallel to the recess 51 and has the same shape as the recess 51. That is, the length of the recess 56 in a longitudinal direction is equal to the length W1 of the recess 51 in the longitudinal direction.

In the present Modification, both the recess 51 and the recess 56 are symmetrical with respect to the straight line L1 passing through the connection position P1 and the connection position P2. As a result, a current passing through the contact portion of the conductive member 42 can be further reduced.

### Second Embodiment

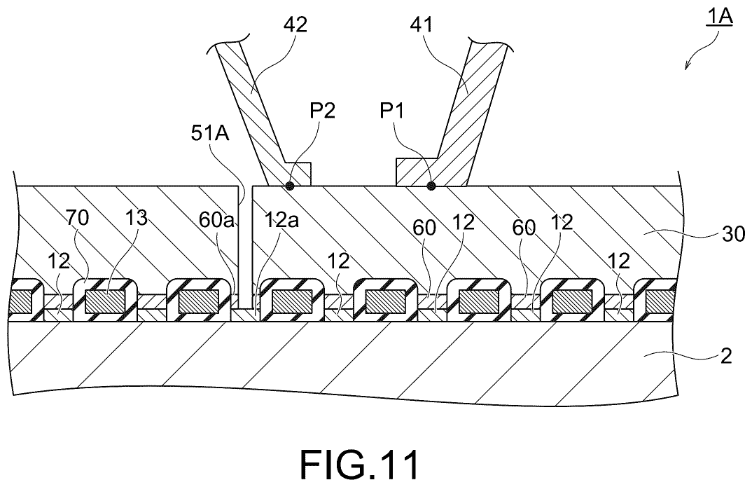

A semiconductor device 1A according to a second embodiment will be described with reference to FIG. 11. FIG. 11 is a cross-sectional view of the semiconductor device 1A according to the second embodiment, taken along line A-A in FIG. 1. One of differences between the first embodiment described above and the present embodiment is the depth of a recess. Hereinafter, the present embodiment will be described focusing on the differences from the first embodiment.

As illustrated in FIG. 11, the semiconductor device 1A according to the present embodiment has a recess 51A instead of the recess 51. The recess 51A penetrates a barrier metal 60a. Upper surfaces of source electrodes 12a, which are some of a plurality of source electrodes 12, are exposed on a bottom surface of the recess 51A. Note that the planar shape of the recess 51A is the same as the planar shape of the recess 51 of the first embodiment.

According to the present embodiment, since electric resistance below the recess 51A increases due to removal of the barrier metal 60a, a current passing through a contact portion of a conductive member 42 can be further reduced.

The semiconductor device 1A according to the present embodiment can be manufactured, for example, by changing RIE condition in the step described with reference to FIG. 7C in the method for manufacturing the semiconductor device 1 according to the first embodiment described above. Note that, in the present embodiment, a conductive layer 30 may be made of a material different from the plurality of source electrodes 12. This facilitates formation of the recess 51A.

### Third Embodiment

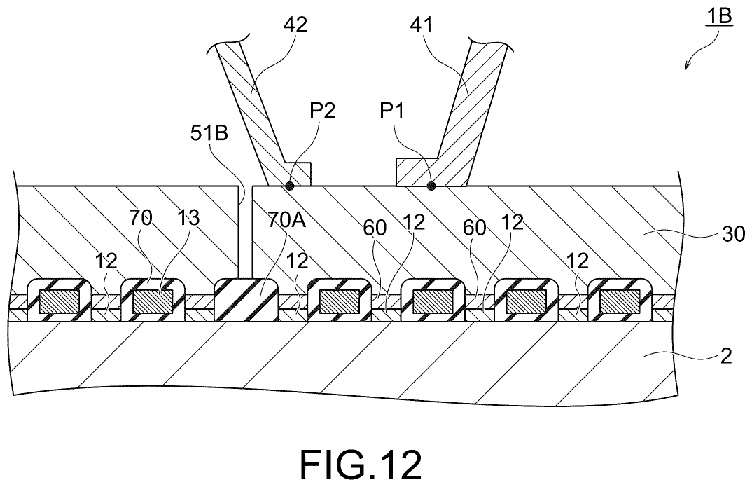

A semiconductor device 1B according to a third embodiment will be described with reference to FIG. 12. FIG. 12 is a cross-sectional view of the semiconductor device according to the third embodiment, taken along line A-A in FIG. 1. One of differences between the first embodiment described above and the present embodiment is a positional relationship between a recess and an insulating region 70. Hereinafter, the present embodiment will be described focusing on the differences from the first embodiment.

As illustrated in FIG. 12, the semiconductor device 1B according to the present embodiment has a recess 51B instead of the recess 51. Upper surfaces of insulating regions 70A, which are some of a plurality of insulating regions 70, are exposed on a bottom surface of the recess 51B. The insulating region 70A is an example of the second insulating region in the claims. In the example of FIG. 12, the width (length in a left-right direction in FIG. 12) of the insulating region 70A is the same as the widths of the other insulating regions 70. Note that the width of the insulating region 70A may be different from the widths of the other insulating regions 70. In addition, the planar shape of the recess 51B is similar to the planar shape of the recess 51 of the first embodiment.

No gate electrode 13 is disposed below the recess 51B. In the present embodiment, no gate electrode 13 is disposed in the insulating region 70A.

According to the present embodiment, since electric resistance on a bottom surface of the recess 51B increases, a current passing through a contact portion of a conductive member 42 can be further reduced.

The semiconductor device 1B according to the present embodiment can be manufactured, for example, by changing the position where the conductive layer 30 is removed in the step described with reference to FIG. 7C in the method for manufacturing the semiconductor device 1 according to the first embodiment described above.

According to the method for manufacturing the semiconductor device 1B according to the present embodiment, since no gate electrode 13 is disposed below the recess 51B, a risk of short-circuiting between the conductive layer 30 and the gate electrode 13 can be reduced.

Note that, in the example of FIG. 12, the insulating region 70A has the same height as the other insulating regions 70. As a result, the insulating region 70A can be collectively formed with the other insulating regions 70.

### Modification of Third Embodiment

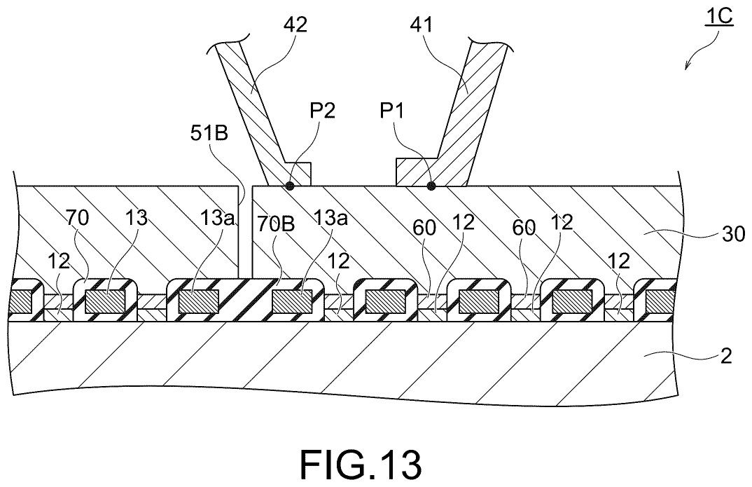

A semiconductor device 1C according to Modification of the third embodiment will be described with reference to FIG. 13. FIG. 13 is a cross-sectional view of the semiconductor device 1C according to Modification of the third embodiment, taken along line A-A in FIG. 1. One of differences between the third embodiment described above and the present Modification is a configuration of an insulating region exposed on a bottom surface of the recess 51B. Hereinafter, the present Modification will be described focusing on the differences from the third embodiment.

As illustrated in FIG. 13, in the present Modification, upper surfaces of insulating regions 70B, which are some of the plurality of insulating regions 70, are exposed on a bottom surface of the recess 51B. The insulating region 70B is an example of the second insulating region in the claims.

No gate electrode 13 is disposed below the recess 51B. More specifically, although two gate electrodes 13a are disposed in the insulating region 70B, none of the two gate electrodes 13a is located below the recess 51B.

According to the present Modification, since electric resistance below the recess 51B increases, a current passing through the contact portion of the conductive member 42 can be further reduced.

According to the method for manufacturing the semiconductor device 1C according to the present Modification, since no gate electrode 13a is disposed below the recess 51B, a risk of short-circuiting between the conductive layer 30 and the gate electrode 13a can be reduced.

### Fourth Embodiment

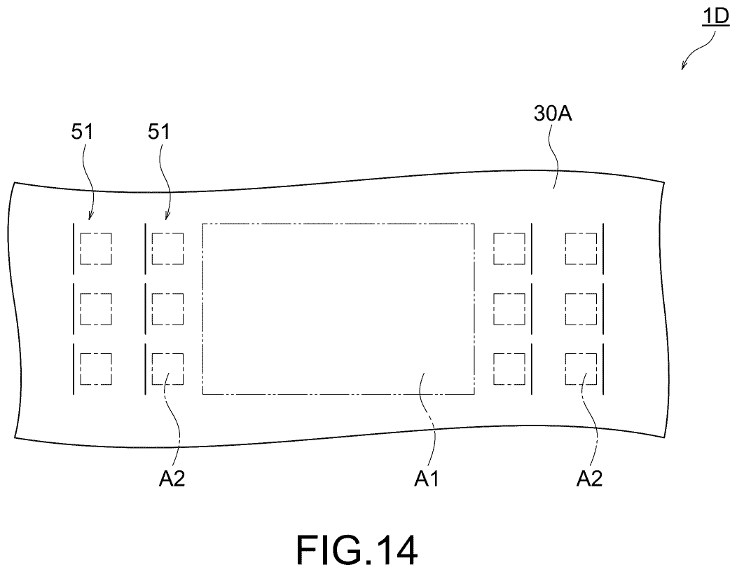

A semiconductor device 1D according to a fourth embodiment will be described with reference to FIG. 14. FIG. 14 is a schematic plan view of the semiconductor device 1D according to the fourth embodiment. One of differences between the first embodiment described above and the present embodiment is the number of recesses 51. Hereinafter, the present embodiment will be described focusing on the differences from the first embodiment.

As illustrated in FIG. 14, in the semiconductor device 1D according to the present embodiment, a conductive layer 30A has regions to which conductive members 41 and 42 can be connected, respectively. That is, the conductive layer 30A has a connection region A1 to which the conductive member 41 can be connected and a plurality of connection regions A2 to which the conductive members 42 can be connected, respectively, on an upper surface thereof. The connection region A1 is an example of the first connection region in the claims. The connection region A2 is an example of the second connection region in the claims.

The conductive member 41 is connected to any position in the connection region A1. Similarly, the conductive member 42 is connected to any position in the connection region A2.

In the example of FIG. 14, the conductive layer 30A has one connection region A1 and the plurality of connection regions A2 on an upper surface thereof. The connection region A1 has an area larger than each of the connection regions A2. In this case, for example, one or more conductive members 41 are connected to any position in the connection region A1. On the other hand, one conductive member 42 is connected to any position in one of the plurality of connection regions A2.

On an upper surface side of the conductive layer 30A, the plurality of recesses 51 are formed on a side opposite to the connection region A1 with the plurality of connection regions A2 interposed therebetween, respectively. Note that the recess according to Modifications 1 to 3 of the first embodiment or the like may be formed instead of at least one of the plurality of recesses 51.

According to the present embodiment, it is possible to improve the degree of freedom of bonding positions of the conductive member 41 and the conductive member 42 in the semiconductor device 1D. In addition, in a case where the plurality of conductive members 41 are connected, it is possible to suppress an increase in resistance of the semiconductor device 1D by the conductive members 41.

Note that, in each of the above-described embodiments, the case where the semiconductor device is a vertical MOSFET has been described. Without being limited thereto, the semiconductor device may be a vertical transistor such as an insulated gate bipolar transistor (IGBT).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a silicon carbide layer having a first main surface and a second main surface, the silicon carbide layer including:
a first-conductivity-type first silicon carbide region;
a second-conductivity-type second silicon carbide region disposed between the second main surface and the first silicon carbide region; and
a first-conductivity-type third silicon carbide region disposed between the second main surface and the second silicon carbide region;
a first electrode disposed on the first main surface;
a plurality of second electrodes disposed on the second main surface;
a third electrode facing the second silicon carbide region via a first insulating region;
a conductive layer electrically connected to the plurality of second electrodes and having a first connection position and a second connection position on an upper surface of the conductive layer;
a first conductive member connected to the first connection position and electrically connected to the conductive layer;
a second conductive member connected to the second connection position and electrically connected to the third electrode and the conductive layer; and
a recess disposed on an upper surface side of the conductive layer and located on a side opposite to the first connection position with the second connection position interposed between the first connection position and the recess.

2. The semiconductor device according to claim 1, further comprising a barrier metal disposed between at least one of the plurality of second electrodes and the conductive layer, wherein
an upper surface of the barrier metal is exposed on a bottom surface of the recess.

3. The semiconductor device according to claim 2, wherein
the conductive layer is made of a material containing at least one of aluminum, copper, titanium, and tungsten, and
the barrier metal is made of a material containing at least one of titanium, tungsten, tantalum, titanium nitride, tungsten nitride, and tantalum nitride.

4. The semiconductor device according to claim 2, wherein the conductive layer is made of a material different from the barrier metal.

5. The semiconductor device according to claim 1, wherein upper surfaces of some of the plurality of second electrodes are exposed on a bottom surface of the recess.

6. The semiconductor device according to claim 1, further comprising a second insulating region disposed on an upper surface of the silicon carbide layer, wherein
an upper surface of the second insulating region is exposed on a bottom surface of the recess.

7. The semiconductor device according to claim 6, wherein the third electrode is not disposed below the recess.

8. The semiconductor device according to claim 6, wherein the third electrode is not disposed in the second insulating region.

9. The semiconductor device according to claim 6, wherein the second insulating region has the same height as the first insulating region.

10. The semiconductor device according to claim 1, wherein
the recess has a first end and a second end, and
the semiconductor device further comprises:
a second recess formed on an upper surface side of the conductive layer and connected to the first end of the recess; and
a third recess formed on the upper surface side of the conductive layer, connected to the second end of the recess, and sandwiching the second connection position together with the second recess.

11. The semiconductor device according to claim 10, wherein
the second recess is connected to the first end of the recess via a first connection recess, and
the third recess is connected to the second end of the recess via a second connection recess.

12. The semiconductor device according to claim 10, wherein the second recess and the third recess extend toward the first conductive member over a second straight line that is perpendicular to a first straight line passing through the first connection position and the second connection position and passes through the second connection position.

13. The semiconductor device according to claim 1, further comprising a fourth recess formed in the conductive layer and located on a side opposite to the recess with the second connection position interposed between the recess and the fourth recess.

14. The semiconductor device according to claim 1, wherein the recess is symmetrical with respect to a first straight line passing through the first connection position and the second connection position.

15. The semiconductor device according to claim 1, wherein a length of the recess in a second direction orthogonal to a first direction directed from the second connection position to the first connection position is equal to or longer than a length of a portion in contact with an upper surface of the conductive layer in the second conductive member in the second direction.

16. The semiconductor device according to claim 1, wherein
the conductive layer has, on the upper surface, a first connection region to which the first conductive member can be connected and a plurality of second connection regions to which the second conductive members can be connected, respectively, and
on an upper surface side of the conductive layer, a plurality of the recesses are formed on a side opposite to the first connection region with the plurality of second connection regions interposed between the first connection region and the recesses, respectively.

17. The semiconductor device according to claim 16, wherein a plurality of the first conductive members are connected in the first connection region.

18. The semiconductor device according to claim 1, wherein at least a part of the recess is filled with a sealing material that seals the conductive layer, the first conductive member, and the second conductive member.

19. The semiconductor device according to claim 1, wherein
the first conductive member is a wire or a metal piece, and
the second conductive member is a wire or a metal piece.

20. The semiconductor device according to claim 1, wherein the semiconductor device is a vertical MOSFET.
